(19) United States
(12) Patent Application Publication
(10) Pub. No.: US 2004/0244829 A1
(43) Pub. Date: Dec. 9, 2004

(54) Coatings for encapsulation of photovoltaic cells

(76) Inventors: Brian K. Rearick, Allison park, PA (US); Truman F. Wilt, Clinton, PA (US); Thomas G. Rukavina, New Kensington, PA (US); Roy E. Dean, Lower Burrell, PA (US)

Correspondence Address: PPG INDUSTRIES, INC., Intellectual Property Department, One PPG Place, Pittsburgh, PA, 15272, US

(21) Appl. No.: 10/454,714

(22) Filed: Jun. 4, 2003

(51) Int. Cl. H01L 31/00

(52) U.S. Cl. 136/251; 136/256

(57) ABSTRACT

Thin film photovoltaic cells having a protective coating as an encapsulant are disclosed. The protective coating is one that imparts durability, moisture resistance and/or abrasion resistance to the photovoltaic layer of the cell. One or more coating layers, either alone or in combination with one or more primer or adhesive layers, can be used. Powder, liquid and electrodeposited coatings can all be used according to the present invention. Methods of making such cells are also disclosed.

### FIELD OF THE INVENTION

The present invention relates to thin film photovoltaic cells. More specifically, the present invention relates to coatings useful for encapsulating such cells, and methods for making the same.

### BACKGROUND INFORMATION

There are many types of thin film photovoltaic cells that have been developed. While various materials and configurations exist among the thin film technology, most thin film photovoltaic cells comprise the following basic elements: a transparent front layer, which may be glass, transparent polymer, or transparent coating; a transparent, conductive top layer or grid that carries away current; a thin central sandwich of semiconductors that form one or more junctions to separate charge; a back contact that is often a metal film; and a backsheet that protects from the environment and that can provide support to the cell if needed.

While thin film photovoltaic cells hold much promise for the future, particularly since they are much cheaper to manufacture than other photovoltaic cells, outdoor stability of the cells has been a problem. Accordingly, cost effective thin film photovoltaic cells that exhibit improved outdoor stability are desired.

### SUMMARY OF THE INVENTION

The present invention is directed to thin film photovoltaic cells. More specifically, the present cells comprise a photovoltaic layer sandwiched between a transparent superstrate and an encapsulant. The encapsulant comprises a protective coating.

While it is noted above that numerous configurations for thin film photovoltaic cells exist, these cells typically comprise a relatively thick encapsulant. “Encapsulant” and like terms are used herein to refer to the layer or layers that protect the photovoltaic layer from the environment; the encapsulant, also referred to in the art as the “backing layer”, “backsheet”, or like terms, is on the side of the photovoltaic layer opposite the transparent front layer. A traditional encapsulant is glass, the use of which poses numerous problems. Glass is a relatively heavy substrate for encapsulant use. In addition to increasing the weight of the photovoltaic cell, the attachment of the glass to the photovoltaic layer typically requires a very labor-intensive laminate procedure. In this procedure, a glue-like substance is typically used to affix the glass to the photovoltaic layer. Ethylene vinylene acetate, or EVA, is a typical compound used for this purpose. EVA is highly flammable, and because it must be used in large quantities to achieve sufficient adhesion and/or moisture resistance, its use for photovoltaic cells can be hazardous. In addition, cells using a glass encapsulant have been found to lack durability, particularly when used outdoors.

The present invention replaces the typical glass/EVA encapsulant with a protective coating. The coating is far cheaper than a glass/EVA encapsulant, and thin film photovoltaic cells using the protective coating are much easier to manufacture; rather than going through the labor-intensive laminate procedure, the protective coating need only be deposited and cured onto the photovoltaic layer. The result is a thin film photovoltaic cell that is much lighter and thinner. The encapsulant of the present invention is typically between about 4 to 10 mils, whereas the EVA alone used in other cells is typically on the order of 18 to 30 mils, with the glass layer making it even thicker. In addition, the protective coating used in the present invention is durable, and different coatings can be used to make the protective coating so as to achieve the desired levels of moisture barrier, exterior durability, abrasion resistance and the like.

### BRIEF DESCRIPTION OF FIGURES

FIG. 1 is a cross section of a thin film photovoltaic cell of one embodiment of the present invention.

FIG. 2 is a cross section of a thin film photovoltaic cell of one embodiment of the present invention.

FIG. 3 is a cross section of a thin film photovoltaic cell of one embodiment of the present invention.

### DETAILED DESCRIPTION OF THE INVENTION

The present invention is directed to a thin film photovoltaic cell comprising: a photovoltaic layer; a transparent superstrate on one side of the photovoltaic layer; and a protective coating on the other side of the photovoltaic layer. Methods for preparing such cells are also within the scope of the present invention.

As will be apparent to those skilled in the art, a photovoltaic cell must necessarily comprise a photovoltaic layer. As used herein, the term “photovoltaic layer” and like terms refer to a layer that is capable of producing a voltage when exposed to radiant energy. Typically, the photovoltaic “layer” will actually be comprised of multiple layers. For example, the photovoltaic layer may comprise a midlayer surrounded on each side by other layers. The midlayer, which can itself be comprised of multiple layers, comprises a voltage or electron generating material; that is, a semi-conducting material. This material is referred to herein as the “electron generating material”, “electron generating layer”, or like terms. The electron generating material can include, for example, amorphous silicon, film crystalline silicon, copper indium diselenide, cadmium telluride (“CdTe”) and/or like materials. This electron generating layer can comprise alternating n-type and p-type semiconductor layers to form a junction, which can be multi junction or single junction. The midlayer is typically sandwiched between two other layers, both of which are conductive. The layer closest to the transparent superstrate will often be comprised of a transparent, conductive oxide. A suitable and often employed oxide is indium tin oxide. In addition, there is typically another conductive layer on the opposite side of the midlayer. This layer is typically a metal layer that has been deposited through, for example, sputtering. Aluminum is a typical metal used for this layer. It will be understood that the electron generating material needs to be exposed on at least one side to radiant energy, so all of the layers that are on one side of the electron generating material should be transparent to such energy. While exemplary photovoltaic layers are described above, any photovoltaic layer can be used according to the present invention.

The photovoltaic cells of the present invention comprise a transparent superstrate on one side of the photovoltaic layer. The transparent superstrate is transparent to radiant energy, particularly light, since it is this energy that will generate the current in the electron generating layer. Typical superstrates include those made from glass or transparent polymers, such as polyimides. Suitable superstrates are commercially available from AFG and Pilkington, and can be purchased either plain or with a conductive oxide already deposited thereon. While as many layers as desired can be deposited between the superstrate and the electron generating layer, as noted above, such layers should be transparent to permit exposure of the electron generating material to radiant energy.

The thin film photovoltaic cells of the present invention further comprise a protective coating as the encapsulant material. A “protective coating” as used herein refers to a coating that imparts at least some degree of durability, moisture barrier and/or abrasion resistance to the photovoltaic layer; the present “protective coating” can comprise one or more coating layers. The protective coating can be derived from any number of known coatings, including powder coatings, liquid coatings and electrodeposited coatings. It is believed that corrosion to one or both of the layers surrounding the electron generating portion of the photovoltaic layers causes failure of the cells, although the inventors do not wish to be bound by this. Use of durable, moisture resistant and/or abrasion resistant coatings as an encapsulant can minimize if not eliminate this corrosion.

Powder coatings are particularly suitable for use in the present invention, in that they can be readily applied in a thick layer. For example, a dry film thicknesses of 1 to 10 mils, such as 4 to 8 mils, can be achieved relatively easily with powder coatings. While any powder coating can be used at any thickness, certain coatings will be more appropriate for the present application. As noted above, the coating should be one that provides the desired level of durability, moisture resistance and/or abrasion resistance to the photovoltaic layer. Particularly suitable powder coatings include thermoset powder coatings. Low cure powder coatings are particularly desired in the present invention, so as to avoid excessive heat being applied to the photovoltaic layer. A thermoset powder coating is one comprising a resin and curing agent; upon heating the curing agent reacts and crosslinks with the resin. A “low-cure” powder coating is a powder coating composition that cures at a temperature of about 80° C. to 170° C. Examples of low cure powder coatings include polyepoxide-based coatings, such as those described in U.S. Pat. No. 5,569,733; another low-cure alternative is a polyester resin that cures with a solid melamine crosslinker. Low cure powder coatings also include UV curable powder coatings, which, as the name implies, are those that cure upon exposure to UV light or other actinic radiation. These coatings will generally comprise some sort of ethylenic unsaturation in their uncured form, such as an acrylate group, a methacrylate group, a vinylether group, styrene and the like. These coatings are also particularly suitable because the amount of heat needed to cure the coatings, that is the heat generated by the UV light exposure, is not significant. Such coatings are widely commercially available.

The powder coating compositions are most often applied by spraying, such as electrostatic spraying, or by the use of a fluidized bed. The powder coating can be applied in a single sweep or in several passes to provide the desired film thickness. Other standard methods for coating can be employed, such as brushing, dipping or flowing. Generally, after application of the ;powder composition, the coated cell is baked at a temperature sufficient to cure the coating. The temperature and cure time will depend on the type of coating used, as discussed above.

Liquid coatings can also be used, again, as long as they provide the desired level of durability, moisture resistance and/or abrasion resistance to the photovoltaic layer. A particularly suitable liquid coating is one comprising a fluoropolymer. Fluoropolymers are generally noted for their excellent exterior durability, and in this case, the use of a fluoropolymer also provides a compliant moisture barrier. Fluoropolymer coatings are commercially available from PPG Industries, Inc. in their DURANAR line of products, and from Keeler & Long in their MEGAFLON line of products.

The liquid coatings can be applied so as to have a dry film thickness of 1 to 4 mils, such as 1.5 to 2.5 mils. The liquid coatings used according to the present invention can be applied by any conventional methods, such as brushing, dipping, flow coating, roll coating, conventional and electrostatic spraying. Spray techniques are most often used. It will be appreciated that thicker coatings are more easily applied with powder coatings than with liquid coatings. The thickness of both the liquid and powder coatings can be adjusted to provide the desired level of protection, it being understood that thicker layers will generally provide greater moisture barrier, exterior durability and/or abrasion resistance.

Liquid coatings can also be cured by heating, such as to temperatures of about 180° F. to 360° F., depending on the coating. Typically, temperatures in the lower end of this range will be desired so as to not damage the electrical connections in the cell. “Two pack” or “two K” liquid coatings can also be used. These coatings will be understood as having a resin in one pack and a crosslinker therefor in another pack; the two packs are mixed shortly before application.

In addition to providing the desired properties for moisture barrier, exterior durability, abrasion resistance and the like, the coatings used according to the present invention should also be capable of adhering to the photovoltaic layer. In some embodiments, it may be desired to use an adhesive or primer in conjunction with the powder or liquid coating. In addition to providing adhesion for the coating the primer layer can also serve to passivate the photovoltaic layer; this is particularly true when an aluminum or other metal layer is sputtered onto or otherwise deposited onto the electron generating material of the photovoltaic layer. This passivation will greatly minimize, if not eliminate, corrosion of that metal layer. In a particularly suitable embodiment, more than one primer layer is deposited; use of two layers helps to ensure that no “pin holes” will be present in the primer layer through which water can pass. If used, the primer layer will typically be less than 0.5 mils, such as 0.2 to 0.3 mils. A particularly suitable primer for use in the present invention is one comprising an aminosilane and an epoxy resin.

Another embodiment of the present invention uses an electrodeposited coating in the protective coating. Particularly suitable for this application are anionic electrodeposited coatings, which provide superior corrosion resistance. Examples include phosphatized epoxy coatings such as POWERCRON 150, commercially available from PPG Industries, Inc. Electrodeposited coatings typically have excellent adhesion to the photovoltaic layer, and provide excellent corrosion resistance to that layer. Electrocoating can be carried out using standard methods, using the sputtered metal layer of the photovoltaic layer as the anode. Cure can then be effected by any means appropriate. Electrodeposition and subsequent cure can produce continuous coating films of 5 to 20 microns in thickness. In one embodiment, the electrodeposited coating is then further coated with a typical topcoat to provide additional desired properties, such as moisture barrier, exterior durability, abrasion resistance and the like. Any suitable topcoat imparting these properties alone or in combination can be used. Because the electrodeposited coating demonstrates excellent adhesion to the photovoltaic layer, there is generally not a need to use a primer or other adhesive layer in this embodiment.

Methods for preparing photovoltaic cells are also within the scope of the present invention. The methods generally comprise: (a) depositing a photovoltaic layer onto a transparent superstrate; (b) depositing a protective coating onto the side of the photovoltaic layer opposite the side of the photovoltaic layer to which the transparent superstrate is attached; and (c) curing the protective coating. Deposition of the photovoltaic layer onto the superstrate can be accomplished, for example, by vapor phase deposition. The manner for depositing and curing the protective coatings according to the present invention are as described above. One or more additional steps, also as described above, can be interjected into the present methods. For example, a primer layer can be deposited onto the photovoltaic layer prior to depositing the protective coating. It will be appreciated that “defects” in the various coatings can occur, which may jeopardize film continuity; these defects can result in current leakage. A common defect, for example, occurs when dirt or other impurities become entrapped in the coating. Use of multiple layers of coatings, particularly relatively thick multiple layers, can help to eliminate problems with film continuity.

The present invention is further directed to a photovoltaic cell wherein the encapsulant comprises a protective coating. A “photovoltaic cell” will be understood as referring to a device for converting radiant energy into electrical or thermal energy for use in power generation. Significantly, the protective coating alone provides the encapsulant for the present photovoltaic cells; no glass or other traditional backing layer is needed, yet superior durability, moisture resistance and/or abrasion resistance results.

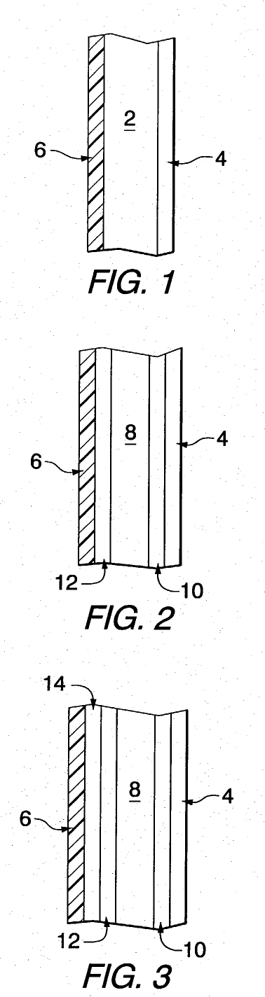

The invention is further illustrated with reference to FIGS. 1-3. FIG. 1 illustrates one embodiment of the invention, wherein the photovoltaic layer 2 is depicted as a single layer. A transparent superstrate 4 is attached to the photovoltaic layer 2 on one side; a protective coating 6 is attached to the photovoltaic layer on the opposite side. FIG. 2 depicts a photovoltaic cell having a multilayer photovoltaic layer according to one embodiment of the invention, wherein the electron generating material 8 is adjacent to a transparent conductive layer 10 on one side and a conductive back contact 12 on the other side. A transparent superstrate 4 is adjacent the transparent conductive layer; a protective coating 6 is adjacent the back contact 12. FIG. 3 similarly shows an electron generating material 8, having first a transparent conductive layer 10 and then a transparent superstrate 4 on one side. On the opposite side of the electron generating material is a back contact 12. A primer layer 14 is shown between back contact 12 and protective coating 6. It will be appreciated that the photovoltaic layer of FIG. 1 is depicted as a single layer, but that multiple layers within the photovoltaic layer can exist. Similarly, the electron generating material 8 depicted in FIGS. 2 and 3 can also be comprised of multiple layers, as can the protective coating 6 shown in all three figures. Finally, any additional coating layers, adhesive layers, or other desirable layers can be included, although not specifically depicted or described herein.

As used herein, unless otherwise expressly specified all numbers such as those expressing values, ranges, amounts or percentages may be read as if prefaced by the word “about”, even if the term does not expressly appear. Any numerical range recited herein is intended to include all sub-ranges subsumed therein. Plural encompasses singular and vice versa. Also, as used herein, the term “polymer” is meant to refer to oligomers and both homopolymers and copolymers; the prefix “poly” refers to two or more.

### EXAMPLES

The following examples are intended to illustrate the invention, and should not be construed as limiting the invention in any way.

Three different primer compositions were prepared using the components listed in Tables 1-3 in the amount as shown. The first primer (“Coating #1”) was prepared by heating the EPON to 100° C. in the presence of propylene glycol monomethyl ether, cyclohexanone and BYK-306 in the ratios indicated in Table 1. The mixture was held at 100° C. until all of the EPON 1009 was dissolved and the mixture was homogeneous. Primers 2 and 3 (“Coating #2” and “Coating #3”, respectively) were prepared by blending the components in the weight percent indicated.

TABLE 1
Coating #1

| Component | Wt. (g) |
|---|---|
| Part A | |
| EPON 1009F Resin¹ | 16.79 |
| Propylene Glycol Monomethyl Ether | 55.84 |
| Cyclohexanone | 23.93 |
| BYK-306² | 0.08 |
| Subtotal | 96.64 |
| Part B | |
| SILQUEST A-1170³ | 3.36 |
| Total | 100.00 |

¹Epoxy resin from Shell Chemical.
²Wetting agent from BYK Chemie.
³Aminosilane from Crompton Corp.

TABLE 2
Coating #2

| Component | Wt % |
|---|---|
| Isopropanol | 98.00 |
| SILQUEST A-1170 | 2.00 |
| Total | 100.00 |

TABLE 3
Coating #3

| Component | Wt % |
|---|---|
| POWERCRON AR150⁴ | 35.29 |
| Ethylene glycol monohexylether | 1.13 |
| DI water | 63.58 |
| Total | 100.00 |

⁴Anionic E-coat from PPG Industries, Inc.

Three liquid topcoats were prepared by mixing the components in Tables 4, 5 and 6, respectively, using agitation with a lift blade until blended.

It will be appreciated that for the 2K coatings, Coatings 4 and 6, Parts A and B were mixed just prior to application.

TABLE 4
(Fluoropolymer Topcoat Composition, Coating #4)

| Component | Wt % |
|---|---|
| Part A | |
| LUMIFLON LF 552 Resin⁵ | 58.81 |
| BAKELITE Epoxy Resin ERL-4299⁶ | 1.29 |
| BYK-354⁷ | 0.35 |
| SILWET L-7500⁸ | 1.69 |
| METACURE T-12 Catalyst⁹ | 0.07 |
| Methyl Isobutyl Ketone | 26.99 |
| Subtotal | 89.20 |
| Part B | |
| DESMODUR Z-4470F¹⁰ | 10.80 |
| Total | 100.00 |

⁵CTFE resin from Asahi Glass.
⁶from Dow Chemical.
⁷Wetting agent from BYK Chemie.
⁸Wetting agent from Crompton Corp.
⁹Catalyst from Air Products, Inc.
¹⁰Isocyanate crosslinker from Bayer.

TABLE 5
(UV-Curable Topcoat Composition, Coating #5)

| Component | Wt % |
|---|---|
| Resin¹¹ | 54.37 |
| IRGACURE 1800¹² | 0.79 |
| Methyl Ethyl Ketone | 2.70 |
| Butyl Acetate | 26.54 |
| VM&P Naphtha Solvent | 15.60 |
| Total | 100.00 |
| ¹¹A mixture of 435.5 parts by weight of 1,3-bis(1-isocyanato-1-methylethyl)benzene, 155.9 parts by weight of 4,4′methylenebis(cyclohexyl isocyanate) and 4.1 parts by weight of dibutyltin dilaurate catalyst were heated to 60° C. At 60° C. Stahl PC-1733 polycarbonate diol was added to the reaction flask at a controlled rate to prevent | |
| # the reaction temperature from exceeding 90° C. Then 1.6 parts by weight of 2,6-di-tert-butyl-4-methylphenol and 0.06 parts by weight of phenothiazine were added to the reaction mixture. After stirring for 5 minutes, 340.7 parts by weight of hydroxypropyl acrylate was added to the reaction flask at a rate which maintained the reaction temperature under 90° C. | |
| # After the addition was complete and the isocyanate equivalent weight exceeded 8400 grams/equivalent, the reaction was diluted with 666.0 parts by weight of n-butyl acetate to yield an acrylate functional resinous solution. | |

¹²photoinitiator from Ciba Specialty Chemicals Corp.

TABLE 6
(MEGAFLON Clearcoat Coating #6)

| Component | Amount |
|---|---|
| MEGAFLON UMS-100080 Part A¹³ | 120 ml |
| MEGAFLON KLMS 210¹⁴ | 20 ml |
| MEGAFLON UMB1 Part B¹⁵ | 8.5 g |

¹³Clear resin from Keeler & Long.
¹⁴Reducing solvent from Keeler & Long.
¹⁵Isocyanate crosslinker from Keeler & Long.

Two different powder topcoat compositions were prepared using the components and weight percents shown in Tables 7 and 8. The ingredients were weighed together and processed for ˜20s in a Prism blender at 3500 rpm's. This premix was then extruded through a b&p Process Equipment and Systems 19 mm, co-rotating, twin screw extruder at 450 rpm's, at temperatures ranging from 80° C. to 130° C. The resultant chip was milled and classified to a median particle size of 20 to 50 μm on a Hosokawa Micron Powder Systems Air Classifying Mill I. The formulas were then electrostatically sprayed using Nordson equipment onto the photovoltaic cells. Finally, the cells were baked in electric Despatch LAD series ovens for a dwell time of 20 to 30 minutes at 380° F. or 330° F. for Coatings #7 and #8, respectively.

TABLE 7
(Fluoropolymer Powder Topcoat Composition, Coating #7)

| Component | Wt % |
|---|---|
| LUMIFLON LF-710 Resin¹⁶ | 61.22 |
| VESTAGON BF 1540¹⁷ | 15.31 |
| RESIFLOW PL-200¹⁸ | 0.82 |
| URAFLOW B¹⁹ | 0.41 |
| TINUVIN 144²⁰ | 0.41 |
| BUTAFLOW BT-71²¹ | 0.82 |
| R-960-38 TiO₂²² | 20.41 |
| IRGANOX 1076²³ | 0.60 |
| Total | 100.00 |

¹⁶CTFE resin from Asahi Glass.
¹⁷Blocked isocyanate crosslinker from DeGussa.
¹⁸Acrylic flow additive deposited on silica from Estron Chemicals.
¹⁹Flow additive from Mitsubishi Chemical Corp.
²⁰UV absorber from Ciba Specialty Chemicals.
²¹Catalyst from Estron Chemicals.
²²from DuPont.
²³Antioxidant from Ciba Additives.

TABLE 8
(Polyester Melamine Powder Topcoat Composition. Coating #8)

| Component | Wt % |
|---|---|
| URALAC P 1580²⁴ | 47.59 |
| RESIFLOW PL-200 | 0.83 |
| TINUVIN 144 | 0.59 |
| IRGANOX 1076 | 1.67 |
| R-960-38 TiO₂ | 17.84 |
| MARTINAL ON-310²⁵ | 17.84 |
| LICOWAX C Micropowder²⁶ | 0.72 |
| 2,2,6,6 tetramethyl-4-hydroxypiperidine²⁷ | 0.14 |
| POWDERMATE 542DG²⁸ | 0.24 |
| Di-p-toluenesulfonimide²⁹ | 0.17 |
| Urea³⁰ | 0.12 |
| MPP2330F Polyethylene Wax³¹ | 0.71 |
| Solid crosslinker³² | 11.54 |
| Total | 840.6 |
| ²⁴Standard durable 40 OH functional polyester from DSM Resins. | |
| ²⁵Aluminum hydroxide from Albemarle Corp. | |
| ²⁶Ethylene bis(stearamide) from Clariant Additives. | |
| ²⁷from CMS Chemical. | |
| ²⁸Degasser from Troy Corp. | |
| ²⁹from PPG Industries, Inc. | |
| ³⁰from PCS Nitrogen. | |
| ³¹from Micropowders, Inc. | |
| ³²The powdered crosslinker was prepared as follows: Into a two-liter four-necked reaction kettle equipped with a thermometer, a mechanic stirrer, a nitrogen inlet, and means for removing the by-product (methanol) were placed 640.0 parts by weight of CYMEL 303 ((methoxymethyl)melamine-formaldehyde resin from Cytec Specialty Chemicals), | |
| # 498.4 parts by weight of p-tert-butyl benzoic acid, and 1.1 part by weight of p-toluenesulfonic acid. The mixture was heated to 145° C. and the temperature was maintained under nitrogen sparge while the methanol by-product was removed from the system. The reaction progress was monitored by sampling the mixture for acid value measurements. | |
| # The reaction was terminated when the acid value was less than 10. | |

Photovoltaic cells having a transparent glass superstrate and a photovoltaic layer were obtained from BP Solar (Toano, Va.). The photovoltaic layer was deposited on the cell, which was mechanically abraded around the edge to expose the glass. Cells were first cleaned using an isopropanol rinse and then coated as follows.

Coating #1 was spray-applied to the panels indicated in Table 9, flashed for five minutes at ambient temperature, and then baked five minutes at 180° F. Coating #1 dry film thicknesses were approximately 0.2 to 0.3 mils. Coating #3 was applied via electrodeposition to the panels indicated in Table 9. Coating #3 was prepared in a 25-gallon tank. The coating was ultrafiltered (50 percent), and the ultra filtration permeate was replaced with an equal volume of DI water. The photovoltaic cell was suspended in the bath (97° F.), with the conductive photovoltaic layer acting as the anode. Coating was applied at 75 volts for three minutes. Coating #3 was then cured for 10 minutes at 300° F. for 10 minutes. Since Coating #3 was only electrodeposited to the conductive photovoltaic layer, glass edges of the cells exposed during abrasion were coated with Coating #2 to ensure adhesion of the topcoat to the entire cell. Coating #2 was applied by wiping the dilute solution onto the glass with a cloth.

After the primer, cells were further coated with a spray-applied topcoat layer as indicated in Table 9. Liquid coatings (Coating #4 or #6) were applied by hand-spraying using a Binks Model 7 suction-feed spray gun. Coatings #4 and #5 were applied in two coats, wet on wet with a 5-minute flash between coats. After the second coat, samples were flashed for 15 minutes, then baked at 180° F. for 20 minutes. Coating #5 was cured using UV radiation (200 Watt Mercury lamps, ˜850 mJ exposure). Coatings #7 and 8 were applied as described above.

TABLE 9

| | | | Topcoat | Adhesion^{A} |
|---|---|---|---|---|
| | Primer | Topcoat | DFT | (Humidity |
| Sample | Composition | Composition | (mil) | Exposure) |
| 1 | Coating #1 | Coating #5 | 3.8 ± 0.6 | 64% (Glass) |
| | | | | 100% (Aluminum) |
| 2 | Coating #1 | Coating #4 | 2.6 ± 0.3 | 100% (Glass) |
| | | | | 100% (Aluminum) |
| 3 | Coating #3 | Coating #4 | 1.7 | 75% (Glass) |
| | | | | 75% (Aluminum) |
| 4 | Coating #1 | Coating #4 | 2.0 | 80% (Glass) |
| | | | | 100% (Aluminum) |
| 5 | Coating #1 | Coating #6 | 1.9 | 90% (Glass) |
| | | | | 90% (Aluminum) |
| 6 | Coating #1 | Coating #7 | 5.1 | 90% (Glass) |
| | | | | 95% (Aluminum) |
| 7 | Coating #1 | Coating #8 | ˜5 | 92% (Glass) |
| | | | | 100% (Aluminum) |
| 8 | — | Coating #8 | ˜5 | 0% (Glass) |
| | | | | 0% (Aluminum) |

^{A}100° F./100% Relative Humidity for 4 days. Cross-hatch adhesion using Nichiban L-24 tape 100% = no adhesion loss noted

As can be seen from Table 9, the coatings used in conjunction with the primer demonstrated very good adhesion to both the glass and aluminum (photovoltaic layer). Coated cells (Samples #1-7) were illuminated using an artificial light source in order to measure the output of electricity. In all cases, the coated units were functioning photovoltaic cells, regardless of the coating system, coating method, or coating cure conditions. The best results in terms of lack of defects in the coatings were seen when using thick, multiple coating layers.

Whereas particular embodiments of this invention have been described above for purposes of illustration, it will be evident to those skilled in the art that numerous variations of the details of the present invention may be made without departing from the invention as defined in the appended claims.

What is claimed is:

1. A thin film photovoltaic cell comprising: (a) a photovoltaic layer; (b) a transparent superstrate on one side of the photovoltaic layer; and (c) a protective coating on the other side of the photovoltaic layer.

2. The photovoltaic cell of claim 1, wherein one or more primer layers are deposited between the photovoltaic layer and the protective coating.

3. The photovoltaic cell of claim 2, wherein each primer layer or layers has a dry film thickness of 0.5 mils or less.

4. The photovoltaic cell of claim 2, wherein the primer comprises an aminosilane and an epoxy resin.

5. The photovoltaic cell of claim 1, wherein the protective coating layer is derived from a powder coating.

6. The photovoltaic cell of claim 5, wherein the powder coating is low cure.

7. The photovoltaic cell of claim 5, wherein the powder coating is UV curable.

8. The photovoltaic cell of claim 5, wherein the powder coating is a thermoset.

9. The photovoltaic cell of claim 8, wherein the thermoset powder coating comprises a polyester film-forming resin and a solid melamine crosslinker.

10. The photovoltaic cell of claim 5, wherein the protective coating layer is derived from a liquid coating.

11. The photovoltaic cell of claim 10, wherein the liquid coating comprises a fluoropolymer.

12. The photovoltaic cell of claim 1, wherein the protective coating is derived from an electrodeposited coating.

13. The photovoltaic cell of claim 12, wherein the electrodeposition coating is an anionic electrodeposited coating.

14. The photovoltaic cell of claim 12, further comprising a topcoat layer on the electrodeposited coating.

15. The photovoltaic cell of claim 1, wherein the transparent superstrate is glass.

16. A thin film photovoltaic cell wherein the encapsulant comprises a protective coating, which comprises one or more coating layers.

17. The thin film photovoltaic cell of claim 16, wherein the encapsulant further comprises one or more primer or adhesive layers.

18. A method for preparing a thin film photovoltaic cell comprising:
(a) depositing a photovoltaic layer onto a transparent superstrate;
(b) depositing a protective coating onto the side of the photovoltaic layer that is not attached to the transparent superstrate; and (c) curing the protective coating.

19. The method of claim 18, wherein the protective coating is derived from a powder coating.

20. The method of claim 18, wherein a liquid protective coating is derived from a liquid coating.

21. The method of claim 18, wherein electrodeposition is used to deposit the protective coating.

22. The method of claim 21, further comprising; the steps of (d) depositing a topcoat on the cured electrodeposited coating; and (e) curing the topcoat.

23. The method of claim 18, further comprising the step of depositing one or more primer or adhesive layers prior to step (b).
